(19) United States
(12) Patent Application Publication
(10) Pub. No.: US 2026/0371530 A1
(43) Pub. Date: Nov. 19, 2026

(54) COMPUTING SYSTEM AND HEAT DISSIPATION ASSISTING DEVICE

(71) Applicant: WISTRON CORPORATION, New Taipei City (TW)

(72) Inventors: Li Ren WANG, New Taipei City (TW); Chun Yu WU, New Taipei City (TW); Meng Wei HSIEH, New Taipei City (TW); Ping Jen CHEN, New Taipei City (TW); Wei Hsuan YU, New Taipei City (TW); Chieh Yu MA, New Taipei City (TW)

(73) Assignee: WISTRON CORPORATION, New Taipei City (TW)

(21) Appl. No.: 19/303,639

(22) Filed: Aug. 19, 2025

(30) Foreign Application Priority Data
May 16, 2025 (TW) 114118569

(51) Int. Cl. H05K 7/20; G06F 1/20

(52) U.S. Cl. CPC H05K 7/2039; G06F 1/20

(57) ABSTRACT

A computing system includes a computing board and a heat dissipation assisting device. The computing board has a first surface and a second surface. The first surface has a thermal interface area. The heat dissipation assisting device includes a structural member, a first spring member, a heat dissipation board, and a fixing member. The first spring member is sandwiched between the computing board and the structural member. The second surface faces the first spring member. The fixing member is configured to fix the heat dissipation board and the structural member to each other, so that the thermal interface area contacts a surface of the heat dissipation board and the first spring member has a first predetermined force to push the computing board towards the heat dissipation board.

### CROSS-REFERENCE TO RELATED APPLICATION

This application claims the priority and benefit of Taiwan Application No. 114118569 filed May 16, 2025, the disclosure of which is hereby incorporated in its entirety by reference herein.

### TECHNICAL FIELD

The present disclosure relates to a computing system, and in particular to a computing system having a heat dissipation assisting device.

### BACKGROUND

### Related Art

System on Wafer (SoW) is an advanced semiconductor technology, which integrates multiple complete system circuits on a single wafer to provide higher computing power. While a computing system with SoW architecture has higher computing power than traditional server motherboards, the wafer also generates more heat energy. When using a heat dissipation board to dissipate heat from a wafer, in order to maximize heat conduction efficiency of the heat dissipation board, the heat dissipation board needs to fit as close as possible to a surface of the wafer.

### SUMMARY

In view of this, in some embodiments, a computing system is provided, which includes a computing board and a heat dissipation assisting device. The computing board has a first surface and a second surface. The first surface has a thermal interface area. The heat dissipation assisting device includes a structural member, a first spring member, a heat dissipation board, and a fixing member. The first spring member is sandwiched between the computing board and the structural member. The second surface faces the first spring member. The fixing member is configured to fix the heat dissipation board and the structural member to each other, so that the thermal interface area contacts a surface of the heat dissipation board and the first spring member has a first predetermined force to push the computing board towards the heat dissipation board.

In some embodiments, the first spring member has a first abutting portion and a plurality of first spring feet. The first abutting portion contacts the second surface, and the first spring feet provide the first predetermined force.

In some embodiments, the computing board has a plurality of voltage regulating modules. The voltage regulating modules are located on the second surface. The first abutting portion has a plurality of perforations. The perforations correspond to the voltage regulating modules.

In some embodiments, the structural member has a guide hole portion on the second surface facing the computing board, and the first abutting portion has a positioning column. The positioning column corresponds to the guide hole portion.

In some embodiments, the structural member has a plurality of guide rails. The guide rails correspond to the first spring feet and are configured to respectively guide the first spring feet.

In some embodiments, the heat dissipation assisting device further includes a second spring member. The second spring member is located between the computing board and the heat dissipation board. A surface of the heat dissipation board has an avoidance groove and a contact portion. The contact portion contacts the thermal interface area. The second spring member has a second abutting portion and a plurality of second spring feet. The second spring feet and the second abutting portion are accommodated in the avoidance groove. In response to the second spring feet abutting against the structural member, the heat dissipation board has a second predetermined force in a direction towards the computing board.

In some embodiments, each of the second spring feet has a positioning hole portion, and each of the fixing members runs through the positioning hole portion.

In some embodiments, the second spring member has a plurality of connecting arms. The connecting arms are connected to sides of the heat dissipation board.

In some embodiments, in response to the first predetermined force and the second predetermined force, a pressure between the thermal interface area and the contact portion is greater than or equal to 30 pound per square inch (Psi).

In some embodiments, the computing board further includes a plurality of computing components and a plurality of heat conducting members. The computing components are located on the first surface, and the heat conducting members are respectively located between the computing components and the surface of the heat dissipation board.

In some embodiments, the heat dissipation assisting device further includes a third spring member and a fourth spring member. The heat dissipation board is located between the third spring member and the structural member, and the structural member is located between the fourth spring member and the heat dissipation board. The third spring member and the fourth spring member are fixed to sandwich and fix the heat dissipation board and the structural member.

In some embodiments, a heat dissipation assisting device is provided, which is suitable for assisting a computing board in heat dissipation. The heat dissipation assisting device includes a structural member, a heat dissipation board, a first spring member, and a fixing member. The first spring member is located between the structural member and the heat dissipation board. The fixing member is configured to fix the heat dissipation board and the structural member to each other, so that the first spring member has a first predetermined force in a direction from the structural member towards the heat dissipation board.

Various embodiments are provided below for detailed description. However, the embodiments are merely used as examples and will not limit the scope of protection of the present disclosure. In addition, some components are omitted from the drawings in the embodiments to clearly show the technical characteristics of the present disclosure. The same reference numerals in all drawings will be used to denote the same or similar components.

### BRIEF DESCRIPTION OF THE DRAWINGS

FIG. 1 is a schematic exploded view of an assembly of a computing system in some embodiments of the present disclosure;

FIG. 2 is a three-dimensional view of the computing system in some embodiments of the present disclosure;

FIG. 3 is a cross-sectional view taken along line A-A in FIG. 2, showing that a heat dissipation board is not fixed to a structural member;

FIG. 4 is a cross-sectional view taken along line A-A in FIG. 2, showing that the heat dissipation board is fixed to the structural member;

FIG. 5 is a schematic exploded view of an assembly of a computing board and a first spring member in some embodiments of the present disclosure;

FIG. 6 is a cross-sectional view taken along line B-B in FIG. 2, showing that the heat dissipation board is not fixed to the structural member;

FIG. 7 is a cross-sectional view taken along line B-B in FIG. 2, showing that the heat dissipation board is fixed to the structural member; and

FIG. 8 is a schematic exploded view of an assembly of the computing system in some embodiments of the present disclosure, showing relative positions of a third spring member and a fourth spring member.

### DETAILED DESCRIPTION

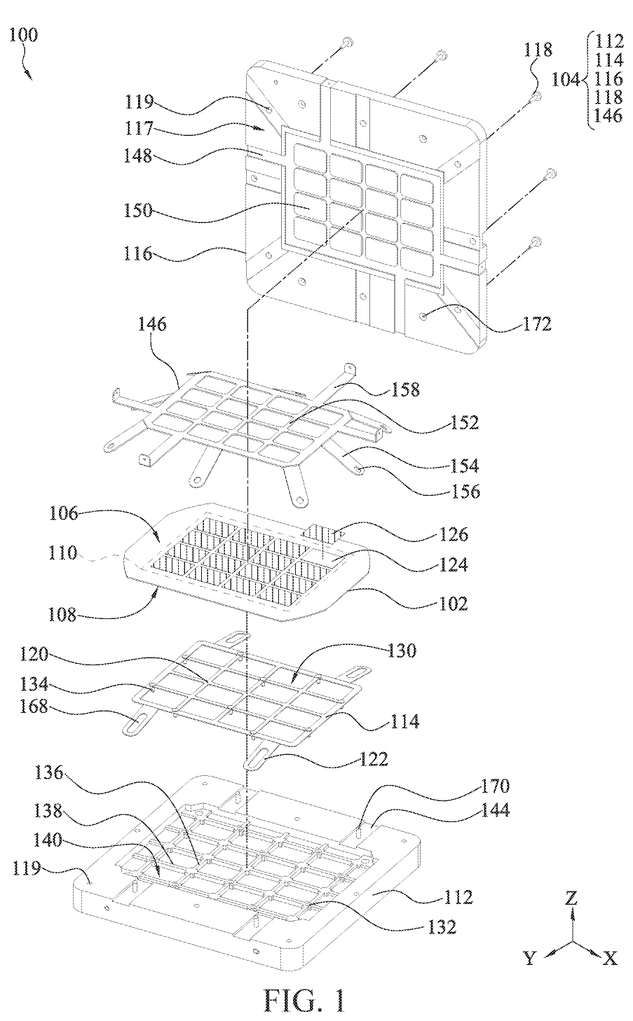

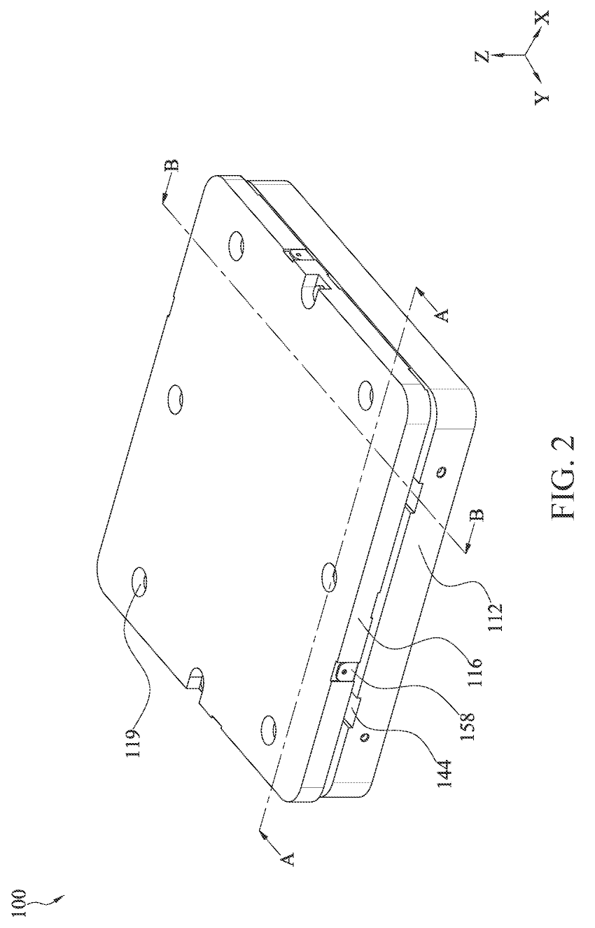

Referring to FIGS. 1 and 2, FIG. 1 is a schematic exploded view of an assembly of a computing system in some embodiments of the present disclosure. FIG. 2 is a three-dimensional view of the computing system in some embodiments of the present disclosure. In some embodiments, as shown in FIGS. 1 and 2, a computing system 100 includes a computing board 102 and a heat dissipation assisting device 104. The computing board 102 has a first surface 106 and a second surface 108. The first surface 106 has a thermal interface area 110. The heat dissipation assisting device 104 includes a structural member 112, a first spring member 114, a heat dissipation board 116, and a fixing member 118. The first spring member 114 is sandwiched between the computing board 102 and the structural member 112. The second surface 108 faces the first spring member 114. The fixing member 118 is configured to fix the heat dissipation board 116 and the structural member 112 to each other, so that the thermal interface area 110 contacts a surface 117 of the heat dissipation board 116 and the first spring member 114 has a first predetermined force to push the computing board 102 towards the heat dissipation board 116. Above structural member 112 is, for example, a carrier member or a base member.

The computing board 102 has one or more heat generating components (e.g., computing components 124 described later). A heat energy generated by the heat generating components during computing may be directly or indirectly conducted to the thermal interface area 110. For example, the heat generating components are arranged on the first surface 106 and concentrated in the thermal interface area 110. The heat energy generated by the heat generating components may be concentrated in the thermal interface area 110, so as to be conducted to the heat dissipation board 116 for heat dissipation. Here, the thermal interface area 110 may refer to an area where the heat generating components contact the heat dissipation board 116. The larger the contact area between the thermal interface area 110 and the heat dissipation board 116, the higher the heat conduction efficiency of the thermal interface area 110 that can be conducted to the heat dissipation board 116 (to be described later).

The heat dissipation assisting device 104 is configured to dissipate heat from the computing board 102, and the computing board 102 may be sandwiched between the structural member 112 and the heat dissipation board 116, so that heat in the thermal interface area 110 can be evenly conducted to the heat dissipation board 116.

The structural member 112 is configured to position the first spring member 114, so as to correspond the first spring member 114 to a position of the computing board 102. The first spring member 114 has a spring force, and may be, for example, a leaf spring or a spring. In some embodiments, the first spring member 114 is exemplified as a leaf spring. As shown in FIG. 1, sides of the first spring member 114 are respectively fixed to the structural member 112, and the rest part may abut against the second surface 108. Here, the first spring member 114 may use the sides as supporting points to generate a pushing force (this pushing force is referred to as the first predetermined force) on the computing board 102.

The first spring member 114 has a spring force, and may be, for example, a leaf spring or a spring. Taking the leaf spring as an example, the computing board 102 presses the first spring member 114 towards the structural member 112, so that the first spring member 114 is bent (as shown in FIG. 1, the first spring member 114 sinks towards the structural member 112) to generate a pushing force towards the heat dissipation board 116. In some embodiments, the first spring member 114 is exemplified as a plurality of springs. One end of each first spring member 114 is fixed to the structural member 112, and the other end abuts against the second surface 108 respectively. In response to the computing board 102 pressing the first spring members 114 towards the structural member 112, each first spring member 114 is pressed to generate a pushing force towards the heat dissipation board 116 respectively.

The fixing member 118 is configured to fix the heat dissipation board 116 to the structural member 112. The fixing member 118 may be, for example, a screw or a rivet. The structural member 112 and the heat dissipation board 116 respectively have a fixing portion 119 matching a number of the fixing members 118, and the fixing portion 119 may be a screw hole or a through hole. The fixing members 118 may determine the number and fixing positions according to a size or shape of the computing board 102. For example, the positions where the fixing members 118 are arranged on the heat dissipation board 116 may be evenly arranged around the computing board 102 and avoid a position of the thermal interface area 110. Here, when the fixing members 118 are connected to the fixing portions 119, the fixing members 118 at each position can not only avoid the computing board 102, but also tightly fix the heat dissipation board 116 to the structural member 112. Thus, the heat dissipation board 116 can evenly contact the thermal interface area 110, so that the thermal interface area 110 can have consistent heat conduction efficiency at different positions.

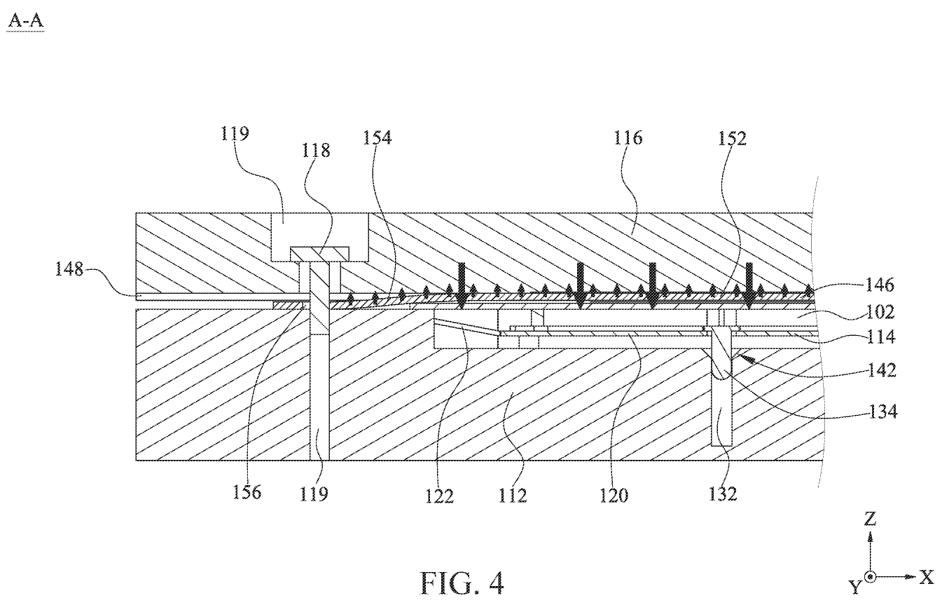

Referring to FIGS. 1, 3, and 4, FIG. 3 is a cross-sectional view taken along line A-A in FIG. 2, showing that a heat dissipation board is not fixed to a structural member. FIG. 4 is a cross-sectional view taken along line A-A in FIG. 2, showing that the heat dissipation board is fixed to the structural member. As shown in FIGS. 1, 3 and 4, the higher the closeness of contact between the thermal interface area 110 and the surface 117, the higher the heat conductivity between the thermal interface area 110 and the heat dissipation board 116. In other words, the heat dissipation assisting device 104 may improve the heat conduction efficiency from the thermal interface area 110 to the heat dissipation board 116 by adjusting the first predetermined force. For example, the first predetermined force may be greater than or equal to 30 Psi. Alternatively, a predetermined force of 30 Psi to 40 Psi may be applied according to an acceptable force range of the computing board 102. When the fixing member 118 presses the heat dissipation board 116 and the structural member 112, the computing board 102 may push the first spring member 114 as the structural member 112 and the heat dissipation board 116 move close to each other. When being pushed, the first spring member 114 generates a reaction force to apply a pushing force to the computing board 102. Thus, the fixing member 118 does not directly contact the computing board 102 or punch holes in the computing board 102, and the computing board 102 can press the thermal interface area 110 against the surface 117 with the aid of this pushing force.

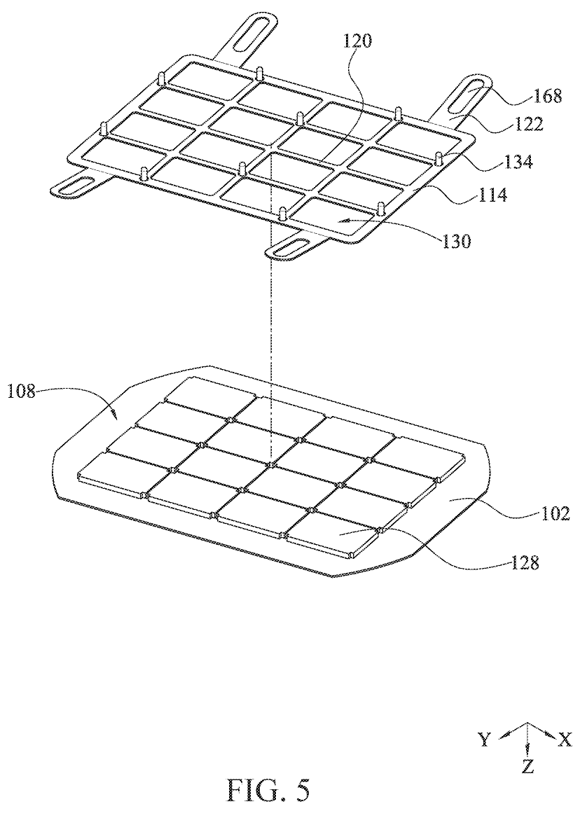

Referring to FIG. 5, FIG. 5 is a schematic exploded view of an assembly of a computing board and a first spring member in some embodiments of the present disclosure. In some embodiments, as shown in FIG. 5, the first spring member 114 has a first abutting portion 120 and a plurality of first spring feet 122. The first abutting portion 120 contacts the second surface 108, and the first spring feet 122 provide the first predetermined force. For example, the first spring feet 122 is positioned to avoid the second surface 108 and are respectively connected to the first abutting portion 120. The first spring feet 122 are connected to sides of the first abutting portion 120 and connected to the structural member 112. When the computing board 102 is pressed towards the structural member 112, the first spring feet 122 may serve as supporting points and pull the first abutting portion 120, so that the first abutting portion 120 generates the first predetermined force to push against the computing board 102.

In some embodiments, the computing board 102 has a plurality of computing components 124 and a plurality of heat conducting members 126. The computing components 124 are located on the first surface 106, and the heat conducting members 126 are respectively located between the computing components 124 and the surface 117. The computing component 124 may be, for example, but not limited to, one or a combination of two or more of a central processing unit (CPU), a graphics processing unit (GPU), an application-specific integrated circuit (ASIC), a field programmable gate array (FPGA), and a tensor processing unit (TPU). The heat conducting member 126 may be, for example, but not limited to, a heat conducting gel, a heat conducting silicone sheet, a heat conducting graphite sheet, a thermal paste, or a liquid metal. Here, the computing components 124 are concentrated in the thermal interface area 110, and the heat conducting member 126 may conduct the heat energy generated by the computing components 124 to the surface 117. Thus, the heat conducting members 126 may serve as heat conducting media between the computing components 124 and the heat dissipation board 116 to fill pores formed on the surface 117 or on surfaces of the computing components 124, so as to increase the closeness between the surface 117 and the surfaces of the computing components 124.

In some embodiments, as shown in FIG. 5, the computing board 102 has a plurality of voltage regulating modules 128. The voltage regulating modules 128 are located on the second surface 108. The first abutting portion 120 has a plurality of perforations 130. The perforations 130 correspond to the voltage regulating modules 128. The voltage regulating modules 128 and the computing components 124 are respectively located on opposite positions on the first surface 106 and the second surface 108, so as to be respectively coupled to the corresponding computing components 124. Therefore, a number of the computing components 124 corresponds to a number of the voltage regulating modules 128. A number of the perforations 130 also corresponds to the number of the voltage regulating modules 128, and the perforations 130 may respectively accommodate the voltage regulating modules 128 in the corresponding positions. When the first abutting portion 120 contacts the second surface 108, the first abutting portion 120 can avoid the voltage regulating modules 128. When the computing board 102 is pressed towards the structural member 112, the voltage regulating modules 128 may run through the perforations 130 (i.e., a height of the first spring feet 122 is greater than a height of the voltage regulating modules 128).

In some embodiments, as shown in FIGS. 1, 3, and 4, the structural member 112 has a guide hole portion 132 on the second surface 108 facing the computing board 102. The first abutting portion 120 has a positioning column 134. The positioning column 134 corresponds to the guide hole portion 132. In a process of assembling the heat dissipation board 116 to the structural member 112, each of the positioning columns 134 may be respectively aligned with each of the plurality of guide hole portions 132 (i.e., each of the positioning columns 134 and each of the plurality of guide hole portions 132 are respectively in a same plumb line). While the positioning columns 134 are guided by the plurality of guide hole portions 132, the heat dissipation board 116 can be properly positioned on the structural member 112, and the voltage regulating modules 128 can run through the perforations 130.

In some embodiments, as shown in FIG. 1, the structural member 112 has a first structural sub-member 136 and a second structural sub-member 138. The first structural sub-member 136 and the second structural sub-member 138 are staggered to form a plurality of opening portions 140 in the structural member 112. The guide hole portion 132 is located at an intersection of the first structural sub-member 136 and the second structural sub-member 138. Here, when the computing board 102 is pushed towards the structural member 112, the voltage regulating modules 128 may be accommodated in the opening portions 140, so as to prevent the voltage regulating modules 128 from being pushed against by the structural member 112.

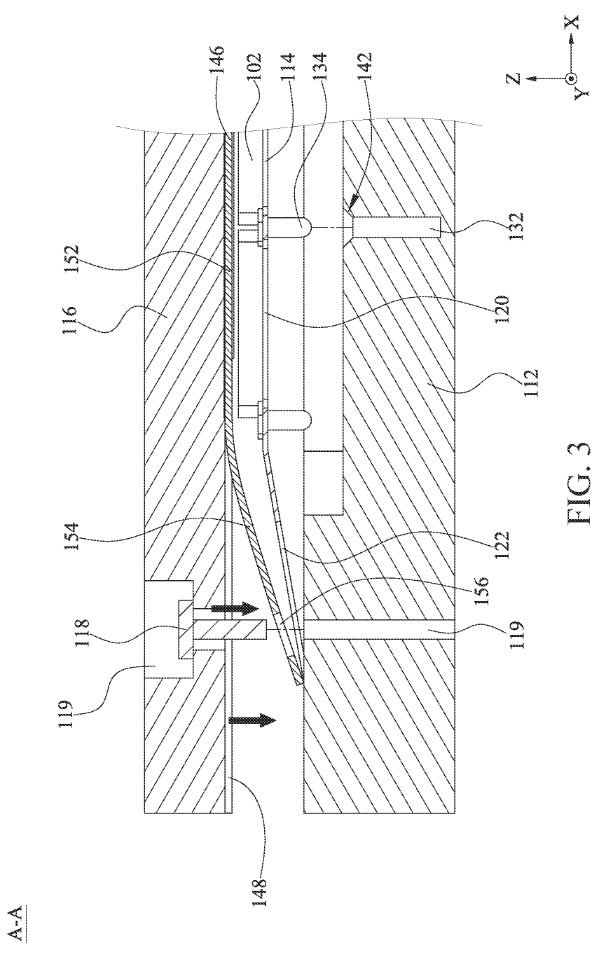

In some embodiments, as shown in FIGS. 3 and 4, each of the plurality of guide hole portions 132 has a guide surface 142 respectively. The guide surface 142 is configured to guide the positioning column 134 into the guide hole portion 132. The guide surface 142 may be inclined or curved, so that the guide hole portion 132 is funnel-shaped as a whole. When the positioning column 134 contacts the guide surface 142, the guide surface 142 may guide the positioning column 134 into the guide hole portion 132.

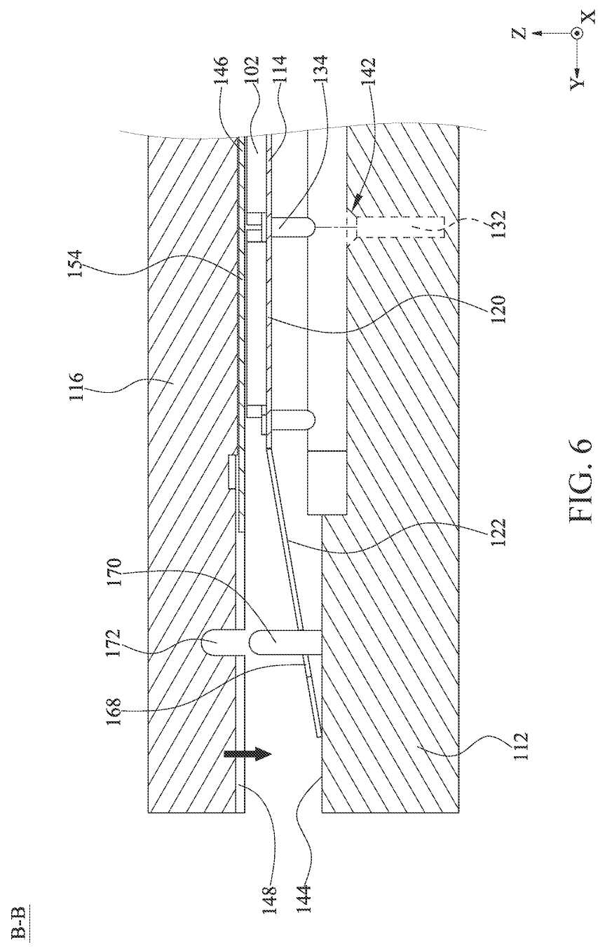

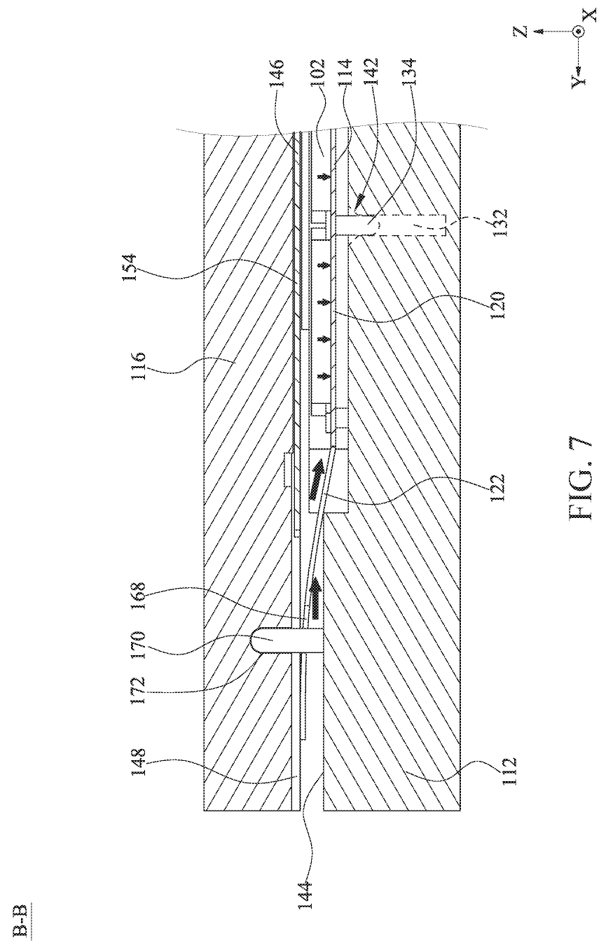

Referring to FIGS. 1, 6, and 7, FIG. 6 is a cross-sectional view taken along line B-B in FIG. 2, showing that the heat dissipation board is not fixed to the structural member. FIG. 7 is a cross-sectional view taken along line B-B in FIG. 2, showing that the heat dissipation board is fixed to the structural member. In some embodiments, as shown in FIGS. 1, 6, and 7, the structural member 112 has a plurality of guide rails 144. The guide rails 144 correspond to the first spring feet 122 and are configured to respectively guide the first spring feet 122. As shown in FIG. 6 and FIG. 7, in a process of fixing the heat dissipation board 116 to the structural member 112, the computing board 102 gradually pushes the first spring member 114 towards the structural member 112, so that the first abutting portion 120 sinks towards the structural member 112 and gradually opens, and thus, the first spring feet 122 are pulled by the first abutting portion 120 and move along predetermined paths of the guide rails 144 (i.e., as shown in FIG. 7, the first spring feet 122 move along a Y-axis). If the computing board 102 is away from the structural member 112 (for example, when the heat dissipation board 116 is removed, the heat dissipation board 116 is not in contact with the computing board 102), the first spring feet 122 may return to original positions along the predetermined paths of the guide rails 144. This ensures that the first spring member 114 remains in its default position when being pressed or restored.

In some embodiments, as shown in FIGS. 1, 3, and 4, the heat dissipation assisting device 104 further includes a second spring member 146. The second spring member 146 is located between the computing board 102 and the heat dissipation board 116. The heat dissipation board 116 has an avoidance groove 148 and a contact portion 150 on the first surface 106 facing the computing board 102. The contact portion 150 contacts the thermal interface area 110. The second spring member 146 has a second abutting portion 152 and a plurality of second spring feet 154. The second spring feet 154 and the second abutting portion 152 are accommodated in the avoidance groove 148. In response to the second spring feet 154 abutting against the structural member 112, the heat dissipation board 116 has a second predetermined force in a direction towards the computing board 102. The second spring member 146 may be, for example, a leaf spring.

The second spring member 146 may be connected to the heat dissipation board 116. During a process of the fixing member 118 fixes the heat dissipation board 116 to the structural member 112, the second spring feet 154 and the second abutting portion 152 may remain in the avoidance groove 148. This prevents the second spring member 146 from abutting against the thermal interface area 110, causing uneven contact between the surface 117 and the thermal interface area 110. The second spring feet 154 may be arranged on sides of the second abutting portion 152 and is positioned to avoid the computing components 124 in the thermal interface area 110. The avoidance groove 148 and the contact portion 150 are offset from the surface 117. The contact portion 150 contacts one of each computing component 124 or heat conducting member 126 in the thermal interface area 110, and the heat energy may be evenly conducted to the heat dissipation board 116 through the contact portions 150.

In some embodiments, as shown in FIGS. 1, 3, and 4, FIG. 3, each of the second spring feet 154 has a positioning hole portion 156, and each of the fixing members 118 runs through the positioning hole portion 156 and positions each of the second spring feet 154 to the structural member 112. Specifically, during a process of fixing the heat dissipation board 116 to the structural member 112 by the fixing member 118, each of the fixing members 118 runs through the positioning hole portion 156 and presses against each of the second spring feet 154, so as to be fixed to the structural member 112. The fixing members 118 may respectively position the second spring feet 154 to default positions of the structural member 112. Positions where the second spring feet 154 are positioned may be evenly distributed on the sides of the structural member 112. Here, when the heat dissipation board 116 is pressed against the structural member 112, the second abutting portion 152 may be accommodated in the avoidance groove 148, so as to avoid pressing against the computing board 102 and affecting the closeness between the surface 117 and the contact portion 150.

The foregoing "in response to the second spring feet 154 abutting against the structural member 112, the heat dissipation board 116 has a second predetermined force in a direction towards the computing board 102" may mean that the fixing members 118 press the heat dissipation board 116 against the structural member 112, and since each of the second spring feet 154 is fixed by the fixing member 118, the second abutting portion 152 is deformed to generate an action force to push towards the heat dissipation board 116. According to a principle of action and reaction forces, the heat dissipation board 116 generates the pushing force towards the computing board 102 (i.e., the second predetermined force) to resist this action force, so that the heat dissipation board 116 is pressed against the thermal interface area 110.

In some embodiments, in response to the first predetermined force and the second predetermined force, a pressure between the thermal interface area 110 and the contact portion 150 is greater than or equal to 30 Psi (or 30 Psi to 40 Psi). Here, the first spring member 114 and the second spring member 146 may distribute the first predetermined force and the second predetermined force according to this pressure range. For example, if an amplitude of the first spring member 114 pushed by the computing board 102 (which refers to a depth to which the first spring member 114 sinks to the structural member 112) is reduced, the first predetermined force may be reduced, and a thickness of the structural member 112 (the thickness may refer to a length of the structural member 112 along a Z-axis in FIG. 4) is also reduced. Alternatively, if an amplitude of deformation of the second spring member 146 (which refers to a height at which the second spring feet 154 raise the second abutting portion 152) is reduced, the second predetermined force may be reduced, and a depth of the avoidance groove 148 (the depth may refer to a length of the avoidance groove 148 along the Z-axis in FIG. 4) is also reduced.

In some embodiments, as shown in FIG. 1, the second spring member 146 has a plurality of connecting arms 158. The connecting arms 158 are connected to sides of the heat dissipation board 116. During the process of fixing the heat dissipation board 116 to the structural member 112, the connecting arms 158 can position the second spring member 146 to a position of the avoidance groove 148, so as to ensure that the second spring member 146 is offset to abut against the first surface 106 of the computing board 102 in the fixing process.

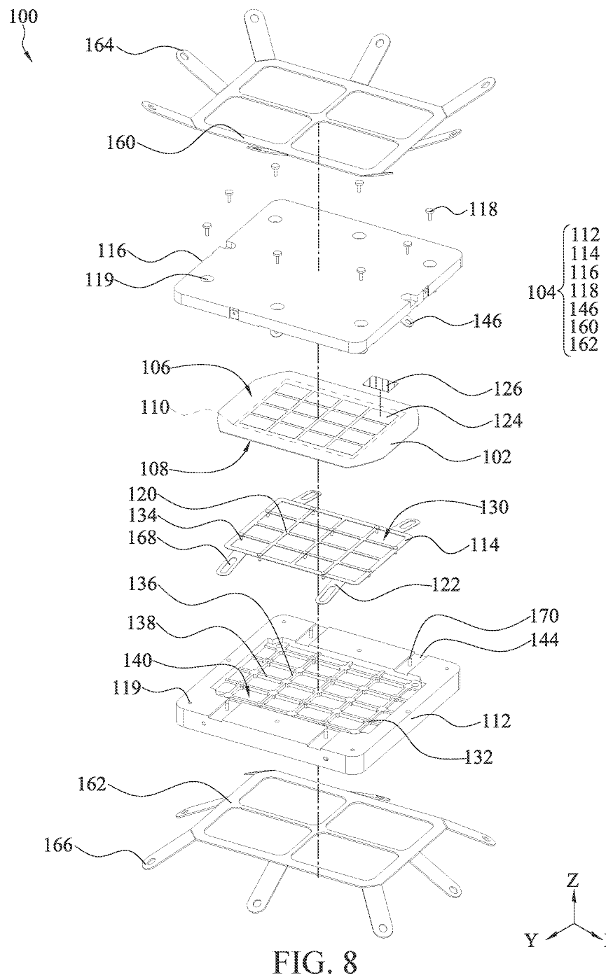

Referring to FIG. 8, FIG. 8 is a schematic exploded view of an assembly of the computing system in some embodiments of the present disclosure, showing relative positions of a third spring member and a fourth spring member. In some embodiments, as shown in FIG. 8, the heat dissipation assisting device 104 further includes a third spring member 160 and a fourth spring member 162. The heat dissipation board 116 is located between the third spring member 160 and the structural member 112, and the structural member 112 is located between the fourth spring member 162 and the heat dissipation board 116. The third spring member 160 and the fourth spring member 162 are fixed to sandwich and fix the structural member 112 and the heat dissipation board 116. The third spring member 160 and the fourth spring member 162 may be fixed to each other, so as to sandwich and fix the structural member 112 and the heat dissipation board 116 between the third spring member 160 and the fourth spring member 162. For example, at least one third spring foot 164 of the third spring member 160 and at least one fourth spring foot 166 of the fourth spring member 162 are locked to each other, so that the third spring member 160 and the fourth spring member 162 sandwich and fix the structural member 112 and the heat dissipation board 116 through these spring feet (164, 166). In response to the third spring member 160 and the fourth spring member 162 being fixed, the third spring member 160 and the fourth spring member 162 may move close to each other. Thus, the third spring member 160 has a pushing force to push the heat dissipation board 116 towards the structural member 112, and the fourth spring member 162 has a pushing force to push the structural member 112 towards the heat dissipation board 116. Under the action forces in two opposite directions (positive and negative directions of the Z-axis in FIG. 8), the structural member 112 and the heat dissipation board 116 are closer to each other, so as to increase the first predetermined force and/or the second predetermined force. For example, in a locking process, the third spring feet 164 and the fourth spring feet 166 are deformed, the third spring member 160 generates a pressure towards the structural member 112, the fourth spring member 162 generates a pressure towards the heat dissipation board 116, and the first predetermined force and/or the second predetermined force is increased according to the direction of application of the pressure.

In some embodiments, as shown in FIGS. 1, 6, and 7, FIG. 6, the first spring feet 122 respectively have a limit hole portion 168. The guide rails 144 respectively have a limit column 170, and the limit column 170 is located in the limit hole portion 168. Two sides of the limit hole portion 168 respectively have a first position and a second position. When the first spring foot 122 is not actuated, the limit column 170 is adjacent to the first position. When the first spring foot 122 is actuated to have the first predetermined force, the limit column 170 is adjacent to the second position. Thus, according to a setting position of the limit column 170or a length of the limit hole portion 168, an amplitude by which the first spring member 114 sinks can be adjusted to control the first predetermined force. For example, the greater the length of the limit hole portion 168, the greater the displacement distance of the first spring feet 122 on the guide rails 144. Under the same amplitude by which the first spring member 114 sinks to the structural member 112, the smaller the length of the limit hole portion 168, the greater the tension generated by the first spring foot 122 on the limit column 170. The greater the tension of the first spring foot 122 on the limit column 170, the greater the first predetermined force. In some embodiments, the heat dissipation board 116 has a plurality of vias 172. When the heat dissipation board 116 is fixed to the structural member 112, the limit columns 170 are respectively located in the vias 172. The position of each limit column 170 corresponding to each via 172 has a positioning function, so that the heat dissipation board 116 can be positioned at the default position of the structural member 112. Here, each fixing member 118 may be aligned with the corresponding fixing portion 119 to avoid misalignment between the heat dissipation board 116 and the structural member 112.

Based on the above, in some embodiments, according to the computing system 100, the first predetermined force to push the computing board 102 towards the heat dissipation board 116 is generated through the first spring member 114 to increase the closeness between the thermal interface area 110 and the surface 117 of the heat dissipation board 116, so that more heat can be conducted between the thermal interface area 110 and the heat dissipation board 116 at the maximum heat conduction efficiency. In some embodiments, according to the computing system 100, the second spring member 146 abuts against the structural member 112, so that the heat dissipation board 116 has the second predetermined force in a direction towards the computing board 102, thereby increasing the closeness between the thermal interface area 110 and the surface 117 of the heat dissipation board 116. Thus, according to the computing system 100, by generating the first predetermined force and the second predetermined force through the first spring member 114 and/or the second spring member 146, the heat dissipation board 116 can be pressed against the computing board 102, so that there is no need to providing the holes in the computing board 102 for the screws to pass through.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A computing system, comprising:
a computing board, having a first surface and a second surface, the first surface having a thermal interface area; and
a heat dissipation assisting device, including:
a structural member ;
a first spring member, sandwiched between the computing board and the structural member, the second surface of the computing board facing the first spring member;
a heat dissipation board; and
a fixing member, configured to fix the heat dissipation board and the structural member to each other, so that a surface of the heat dissipation board being contacted by the thermal interface area, wherein the first spring member is configured to impose a first predetermined force, and the computing board is pushed towards the heat dissipation board via the first predetermined force.

2. The computing system according to claim 1, wherein the first spring member includes a first abutting portion and a plurality of first spring feet, the second surface being contacted by the first abutting portion, and the first predetermined force being provided by the first spring feet.

3. The computing system according to claim 2, wherein the computing board includes a plurality of voltage regulating modules, the voltage regulating modules being located on the second surface, the first abutting portion having a plurality of perforations, and the plurality of perforations corresponding to the plurality of voltage regulating modules.

4. The computing system according to claim 2, wherein the structural member includes a guide hole portion on the second surface facing the computing board, and the first abutting portion includes a positioning column, the positioning column corresponding to the guide hole portion.

5. The computing system according to claim 2, wherein the structural member includes a plurality of guide rails, the plurality of guide rails corresponding to the first spring feet and being configured to respectively guide the first spring feet.

6. The computing system according to claim 1, wherein the heat dissipation assisting device further includes a second spring member located between the computing board and the heat dissipation board, and the surface of the heat dissipation board includes an avoidance groove and a contact portion, the thermal interface area contacted by the contact portion, the second spring member having a second abutting portion and a plurality of second spring feet, and the second spring feet and the second abutting portion being accommodated in the avoidance groove; and in response to the second spring feet abutting against the structural member, the heat dissipation board includes a second predetermined force, and the computing board is pushed towards the heat dissipation board via the second predetermined force.

7. The computing system according to claim 6, wherein each of the second spring feet includes a positioning hole portion, and each of the fixing members runs through the positioning hole portion.

8. The computing system according to claim 6, wherein the second spring member includes a plurality of connecting arms, the plurality of connecting arms being connected to sides of the heat dissipation board.

9. The computing system according to claim 6, wherein in response to the first predetermined force and the second predetermined force, a pressure between the thermal interface area and the contact portion is greater than or equal to 30 Psi.

10. The computing system according to claim 1, wherein the computing board further includes a plurality of computing components and a plurality of heat conducting members, the computing components being located on the first surface, and the plurality of heat conducting members being respectively located between the plurality of computing components and the surface.

11. The computing system according to claim 1, wherein the heat dissipation assisting device further includes a third spring member and a fourth spring member; the heat dissipation board is located between the third spring member and the structural member, and the structural member is located between the fourth spring member and the heat dissipation board; and the heat dissipation board and the structural member are fixed and sandwiched by fixing the third spring member and the fourth spring member to each other.

12. A heat dissipation assisting device, suitable for assisting a computing board in heat dissipation, comprising:
a structural member;
a heat dissipation board;
a first spring member, located between the structural member and the heat dissipation board; and
a fixing member, configured to fix the heat dissipation board and the structural member to each other, so that the first spring member imposes a first predetermined force in a direction from the structural member towards the heat dissipation board.

13. The heat dissipation assisting device according to claim 12, wherein the first spring member includes a first abutting portion and a plurality of first spring feet, the first spring feet being connected to sides of the first abutting portion, and the first predetermined force being provided via the first spring feet.

14. The heat dissipation assisting device according to claim 13, wherein the structural member includes a guide hole portion on a surface facing the heat dissipation board, and the first abutting portion includes a positioning column, the positioning column corresponding to the guide hole portion.

15. The heat dissipation assisting device according to claim 13, wherein the structural member includes a plurality of guide rails, the plurality of guide rails corresponding to the first spring feet and being configured to respectively guide the first spring feet.

16. The heat dissipation assisting device according to claim 12, further comprising a second spring member, located between the structural member and the heat dissipation board, wherein a surface of the heat dissipation board includes an avoidance groove and a contact portion, the contact portion contacting a thermal interface area of the computing board, the second spring member having a second abutting portion and a plurality of second spring feet, and the second spring feet and the second abutting portion being accommodated in the avoidance groove; and in response to the second spring feet abutting against the structural member, the heat dissipation board includes a second predetermined force in a direction towards the structural member.

17. The heat dissipation assisting device according to claim 16, wherein each of the second spring feet includes a positioning hole portion, and each of the fixing members runs through the positioning hole portion.

18. The heat dissipation assisting device according to claim 16, wherein the second spring member includes a plurality of connecting arms, the plurality of connecting arms being connected to sides of the heat dissipation board.

19. The heat dissipation assisting device according to claim 16, wherein in response to the first predetermined force and the second predetermined force, a pressure between the thermal interface area and the contact portion is greater than or equal to 30 Psi.

20. The heat dissipation assisting device according to claim 12, further comprising a third spring member and a fourth spring member, wherein the heat dissipation board is located between the third spring member and the structural member, and the structural member is located between the fourth spring member and the heat dissipation board; and the heat dissipation board and the structural member are fixed and sandwiched by fixing the third spring member and the fourth spring member to each other.
